(19) United States
(12) Patent Application Publication
(10) Pub. No.: US 2026/0113897 A1
(43) Pub. Date: Apr. 23, 2026

(54) LIQUID COOLING DEVICE WITH SELF-CONFIGURING COLD AND HEAT SOURCES

(71) Applicant: SUZHOU METABRAIN INTELLIGENT TECHNOLOGY CO., LTD., Suzhou, Jiangsu (CN)

(72) Inventors: Jian SHENG, Suzhou, Jiangsu (CN); Jian LU, Suzhou, Jiangsu (CN); Wenxue Li, Suzhou, Jiangsu (CN)

(21) Appl. No.: 19/168,001

(22) PCT Filed: Aug. 1, 2024
(86) PCT No.: PCT/CN2024/109243

§ 371 Date: Sep. 23, 2025

(30) Foreign Application Priority Data
Jan. 31, 2024 (CN) 202410133157.5

(51) Int. Cl. H05K 7/20

(52) U.S. Cl. CPC H05K 7/20809; H05K 7/20836

(57) ABSTRACT

A liquid cooling device with self-configuring cold and heat sources is disclosed, including a cabinet, a cold source circulation system, a first heat exchanger, a liquid supply circulation system, and a controller; wherein the cold source circulation system is configured to drive a refrigerant to circularly flow and cool the refrigerant; the liquid supply circulation system is configured to drive cooling liquid to circularly flow and enable the cooling liquid to flow through a cold plate to absorb heat of a load; the first heat exchanger is configured to facilitate heat exchange between the cooled refrigerant and the cooling liquid after absorbing heat; and the controller is in signal connection with the cold source circulation system and is configured to control an operation state of the cold source circulation system according to a heat dissipation requirement of the load.

### CROSS-REFERENCE TO RELATED APPLICATION

The present application claims priority to Chinese Patent Application No. 202410133157.5, filed on Jan. 31, 2024 with the China National Intellectual Property Administration and entitled “Liquid Cooling Device With Self-Configuring Cold and Heat Sources”, which is hereby incorporated by reference in its entirety.

### FIELD

The present application relates to the technical field of liquid cooling, and in particular, to a liquid cooling device with self-configuring cold and heat sources.

### BACKGROUND

Currently, commonly used liquid cooling technologies for servers primarily include immersion liquid cooling and cold-plate liquid cooling. The immersion liquid cooling directly submerges the servers into dedicated cooling liquid for heat dissipation. Due to high comprehensive use cost and maintenance difficulties, the immersion liquid cooling is small in application scale. The cold-plate liquid cooling utilizes cold plates that contact heat-generating components of the servers for heat dissipation. A heat dissipation principle of the cold-plate liquid cooling involves a water pump continuously driving the cooling liquid to flow through channels inside the cold plates, facilitating heat exchange between the cooling liquid and the heat-generating components of the servers through walls of the cold plates, thereby taking away heat generated by the operation of the heat-generating components of the servers.

In related art, a conventional cold-plate liquid cooling system mainly includes an outdoor cold source, a primary-side pump-driving system, a primary-side pipe-network system, a cooling liquid pump-driving heat exchange unit, a secondary-side pipe-network system, and a water distributor. The system lacks an independent cold source and necessarily relies on outdoor cold sources such as an outdoor water chiller or a cooling tower and the primary-side circulation system to complete heat exchange with the liquid-cooled servers. However, a construction process of the conventional cold-plate liquid cooling system not only requires the procurement and installation of facilities such as the outdoor water chiller, the cooling tower, primary-side and secondary-side cooling liquid circulation pipelines, and power systems, but also involves extensive engineering designs including substantial infrastructure construction and infrastructure modifications, and has drawbacks of high construction difficulty, long construction period, and large resource investment. Consequently, it is challenging for conventional air-cooled data centers to be upgraded and transformed into liquid-cooled data centers by using solutions in the related art, making the server unable to implement convenient and low-cost cold-plate liquid cooling. Furthermore, a heat dissipation state of the outdoor cold source is closely tied to external environmental conditions, making the heat dissipation state uncontrollable, and causing problems such as insufficient or excessive cooling capacity provided by the outdoor cold source.

### SUMMARY

The present application provides a liquid cooling device with self-configuring cold and heat sources, which includes a cabinet, a cold source circulation system, a first heat exchanger, a liquid supply circulation system, and a controller;
the cold source circulation system, the first heat exchanger, the liquid supply circulation system, and the controller are all integrated on the cabinet;
the cold source circulation system is configured to drive a refrigerant to circularly flow along a preset path, and cool the refrigerant;
the liquid supply circulation system is configured to drive cooling liquid to circularly flow along a preset path, and drive the cooling liquid to flow through a cold plate to absorb heat of a load;
the first heat exchanger is connected between the cold source circulation system and the liquid supply circulation system, and configured to facilitate heat exchange between the cooled refrigerant and the cooling liquid after absorbing heat; and
the controller is in signal connection with the cold source circulation system, and is configured to control an operation state of the cold source circulation system according to a heat dissipation requirement of the load.

In another aspect, the cold source circulation system includes a compressor, a condenser, and an expansion valve; and
an outlet of the compressor is in communication with an inlet of the condenser, an outlet of the condenser is in communication with an inlet of the expansion valve, an outlet of the expansion valve is in communication with an inlet of an evaporation heat exchange pipeline of the first heat exchanger, and an outlet of the evaporation heat exchange pipeline of the first heat exchanger is in communication with an inlet of the compressor.

In another aspect, the liquid cooling device with self-configuring cold and heat sources further includes a first temperature sensor for detecting an inlet temperature of the evaporation heat exchange pipeline, a second temperature sensor for detecting an outlet temperature of the evaporation heat exchange pipeline, a first pressure sensor for detecting inlet pressure of the evaporation heat exchange pipeline, and a second pressure sensor for detecting outlet pressure of the evaporation heat exchange pipeline; and
the controller is in signal connection with the first temperature sensor, the second temperature sensor, the first pressure sensor, and the second pressure sensor, and is configured to determine a current heat dissipation requirement of the load according to detected values of the four sensors and control an operation state of the compressor according to the requirement.

In another aspect, the liquid cooling device with self-configuring cold and heat sources further includes a filter dehumidifier connected between the outlet of the condenser and the inlet of the expansion valve, and the filter dehumidifier is configured to filter water and impurities in the refrigerant.

In another aspect, the liquid supply circulation system includes a temperature regulation module, a cold plate liquid supply module, and a cold plate liquid return module;
an inlet of the temperature regulation module is in communication with an outlet of a condensation heat exchange pipeline of the heat exchanger, and the temperature regulation module is configured to regulate the temperature of the cooling liquid and is in signal connection with the controller, whereby an operation state of the temperature regulation module is controlled according to a heat dissipation requirement of the load;
an inlet of the cold plate liquid supply module is in communication with an outlet of the temperature regulation module, an outlet of the cold plate liquid supply module is in communication with an inlet of the load, and configured to supply liquid to the load; and
an inlet of the cold plate liquid return module is in communication with an outlet of the load, and an outlet of the cold plate liquid return module is in communication with an inlet of the condensation heat exchange pipeline of the first heat exchanger, and configured to drive the cooling liquid to circularly flow.

In another aspect, the temperature regulation module includes a temperature regulation water storage tank for temporary storage of cooling liquid, a heater disposed in the temperature regulation water storage tank, and a water tank temperature sensor for detecting the temperature of the cooling liquid in the temperature regulation water storage tank; and the water temperature sensor and the heater are both in signal connection with the controller, whereby the controller controls an operation state of the heater according to a detected value of the water tank temperature sensor and the heat dissipation requirement of the load.

In another aspect, the temperature regulation module further includes a liquid level meter for detecting a liquid level of the cooling liquid that is temporarily stored in the temperature regulation water storage tank, and a liquid replenishment mechanism and a liquid discharge mechanism in communication with the temperature regulation water storage tank, and the liquid level meter is in signal connection with the controller, whereby the controller controls operation states of the liquid replenishment mechanism and liquid discharge mechanism according to a difference between a detected value of the liquid level meter and a preset threshold.

In another aspect, the cold plate liquid supply module includes a distal liquid inlet pipe and a proximal liquid inlet pipe;
an inlet of the distal liquid inlet pipe is in communication with the outlet of the condensation heat exchange pipeline of the first heat exchanger, and an outlet of the distal liquid inlet pipe is in communication with the temperature regulation water storage tank; and an inlet of the proximal liquid inlet pipe is in communication with the temperature regulation water storage tank, and an outlet of the proximal liquid inlet pipe is in communication with the inlet of the load.

In another aspect, the cold plate liquid supply module further includes a distal bypass liquid inlet pipe and a distal bypass regulation valve;
an inlet of the distal bypass liquid inlet pipe is in communication with the distal liquid inlet pipe, and an outlet of the distal bypass liquid inlet pipe is in communication with the cold plate liquid return module; and
the distal bypass regulation valve is disposed on the distal bypass liquid inlet pipe and configured to enable a portion of cooling liquid to enter the cold plate liquid return module through the distal bypass liquid inlet pipe when the detected value of the water tank temperature sensor is less than a preset threshold.

In another aspect, the cold plate liquid supply module further includes a water distributor; and
the water distributor is disposed in the temperature regulation water storage tank, an inlet of the water distributor is in communication with the outlet of the distal liquid inlet pipe, the water distributor is provided with a plurality of outlets distributed along a height direction of the temperature regulation water storage tank, and configured to allocate the cooling liquid equally to each layer in the water regulation water storage tank.

In another aspect, the cold plate liquid supply module further includes a proximal bypass liquid inlet pipe and a proximal bypass regulation valve;
an inlet of the proximal bypass liquid inlet pipe is in communication with the proximal liquid inlet pipe, and an outlet of the proximal bypass liquid inlet pipe is in communication with the cold plate liquid return module; and
the proximal bypass regulation valve is disposed on the proximal bypass liquid inlet pipe and configured to enable a portion of cooling liquid to enter the cold plate liquid return module through the proximal bypass liquid inlet pipe when a cooling liquid demand of the load is less than a minimum flow rate of returned liquid of the cold plate liquid return module.

In another aspect, the cold plate liquid supply module further includes a disinfection component disposed on the proximal liquid inlet pipe and configured to kill harmful microorganisms in the cooling liquid.

In another aspect, the cold plate liquid supply module further includes a monitoring component disposed on the proximal liquid inlet pipe and configured to make a flow state of the cooling liquid visible.

In another aspect, the cold plate liquid supply module further includes at least two filters that are parallel connected onto the proximal liquid inlet pipe, first on-off valves that are separately disposed on the outlet and inlet ends of each filter, and water quality sampling valves in communication with the inlets of the filters respectively; and
the first on-off valve is configured to close a branch in which the corresponding filter is located when a filter element of the corresponding filter is maintained.

In another aspect, the cold plate liquid supply module further includes monitoring pressure sensors that are respectively disposed at the inlet and outlet ends of each filter, each monitoring pressure sensor is in signal connection with the controller, whereby the controller issues a filter element maintenance alarm when a difference between detected values of the monitoring pressure sensors at both ends is greater than a preset threshold.

In another aspect, the cold plate liquid return includes a proximal liquid return pipe, a distal liquid return pipe, a proximal circulation pump, and a distal circulation pump; an inlet of the proximal liquid return pipe is in communication with the outlet of the load, and an outlet of the proximal liquid return pipe is in communication with the temperature regulation water storage tank;
an inlet of the distal liquid return pipe is in communication with the temperature regulation water storage tank, and an outlet of the distal liquid return pipe is in communication with the inlet of the condensation heat exchange pipeline of the first heater exchanger;
the proximal circulation pump is disposed on the proximal liquid return pipe, and configured to drive the cooling liquid to flow into the temperature regulation water storage tank from the outlet of the load; and
the distal circulation pump is disposed on the distal liquid return pipe, and configured to drive the cooling liquid to flow into the inlet of the condensation heat exchange pipeline of the first heat exchanger from the temperature regulation water storage tank.

In another aspect, the inlet and outlet ends of both the proximal circulation pump and the distal circulation pump are respectively in communication with vibration damping pipes, and the vibration damping pipes are configured to eliminate an installation error generated when the proximal circulation pump or the distal circulation pump is connected with the pipeline and reduce the vibration generated when the proximal circulation pump or the distal circulation pump is operated through elastic deformation.

In another aspect, the inlet and outlet ends of both the proximal circulation pump and the distal circulation pump are respectively in communication with second on-off valves, and the second on-off valves are configured to close the corresponding proximal liquid return pipe or the distal liquid return pipe when the proximal circulation pump or the distal circulation pump is overhauled.

In another aspect, the cold plate liquid return module further includes a water collector; and
the water collector is disposed in the temperature regulation water storage tank, an outlet of the water collector is in communication with the inlet of the distal liquid return pipe, the water collector is provided with a plurality of inlets that are distributed along a height direction of the temperature regulation water storage tank and configured to enable the cooling liquid at each layer in the temperature regulation water storage tank to be pumped out by the distal circulation pump.

In another aspect, the liquid cooling device with self-configuring cold and heat sources further includes an isolated circulation system and a second heat exchanger;
the isolated circulation system and the second heat exchanger are both integrated on the cabinet;
the isolated circulation system is disposed between the cold source circulation system and the liquid supply circulation system, and configured to drive an intermediate heat-conducting medium to circularly flow along a preset path, and transfer the heat from the cooling liquid in the liquid supply circulation system to the refrigerant in the cold source circulation system through the first heat exchanger; and
the second heat exchanger is connected between the isolated circulation system and the liquid supply circulation system, and configured to facilitate heat exchange between the intermediate heat-conducting medium and the cooling liquid after absorbing heat.

In another aspect, the isolated circulation system includes an isolated liquid supply module and an isolated liquid return module;
an inlet of the isolated liquid supply module is in communication with the outlet of the condensation heat exchange pipeline of the first heat exchanger, and an outlet of the isolated liquid supply module is in communication with an inlet of a heat absorbing pipeline of the second heat exchanger; and
an inlet of the isolated liquid return module is in communication with an outlet of the heat absorbing pipeline of the second heat exchanger, and an outlet of the isolated liquid return module is in communication with the inlet of the condensation heat exchange pipeline of the first heat exchanger.

In another aspect, the isolated liquid supply module includes a main liquid supply pipe and a branch liquid supply pipe;
an inlet of the main liquid supply pipe is in communication with the outlet of the condensation heat exchange pipeline of the first heat exchanger, and an outlet of the main liquid supply pipe is in communication with the inlet of the heat absorbing pipeline of the second heat exchanger;

an inlet of the branch liquid supply pipe is in communication with the main liquid supply pipe, and an outlet of the branch liquid supply pipe is in communication with the isolated liquid return module; and
the branch liquid supply pipe is provided with a branch regulation valve, the branch regulation valve is configured to enable a portion of intermediate heat-conducting medium to enter the isolated liquid return module through the branch liquid supply pipe when the cooling capacity supplied by the main liquid supply pipe to the heat absorbing pipeline of the second heat exchanger is greater than the heat released by a heat release pipeline of the second heat exchanger.

In another aspect, the isolated liquid return module includes a main liquid return pipe, an isolated circulation pump, and a pressure stabilizing tank;
the inlet of the main liquid return pipe is in communication with the outlet of the heat absorbing pipeline of the second heat exchanger, and an outlet of the main return pipe is in communication with the inlet of the condensation heat exchange pipeline of the first heat exchanger;
the isolated circulation pump is disposed on the main liquid return pipe, and configured to drive the intermediate heat-conducting medium to circularly flow in the main liquid supply pipe and the main liquid return pipe; and
the pressure stabilizing tank is serially connected into the main liquid return pipe, and configured to regulate and control pressure and/or flow rate of the intermediate heat-conducting medium in the isolated circulation system according to a preset target parameter.

In another aspect, at least two isolated circulation pumps are provided, and all isolated circulation pumps are parallel connected onto the main liquid return pipe; and the inlet and outlet ends of all isolated circulation pumps are respectively provided with third on-off valves, and the third on-off valves are configured to close a branch in which the corresponding isolated circulation pump is located when the corresponding isolated circulation pump is maintained.

In another aspect, the isolated circulation system further includes a liquid replenishment tank, a preset amount of intermediate heat-conducting medium is stored in the liquid replenishment tank, and an outlet of the liquid replenishment tank is in communication with the pressure stabilizing tank, and configured to replenish the intermediate heat-conducting medium when the amount of the intermediate heat-conducting medium in the pressure stabilizing tank is reduced.

### BRIEF DESCRIPTION OF THE DRAWINGS

In order to describe the embodiments of the present application or the technical solutions in the related art more clearly, drawings required to be used in the embodiments or the illustration of the related art will be briefly introduced below. Apparently, the drawings described below are only some embodiments of the present application. Those ordinarily skilled in the art can also obtain other drawings according to the provided drawings without contributing creative work.

FIG. 1 is a schematic structural diagram of a cabinet according to a specific implementation of the present application.

FIG. 2 is a schematic diagram of a system architecture according to a first specific implementation of the present application.

FIG. 3 is a schematic diagram of a system architecture according to a second specific implementation of the present application.

FIG. 4 is a schematic diagram of specific system modules of the system architecture shown in FIG. 2.

FIG. 5 is a schematic diagram of specific system modules of the system architecture shown in FIG. 3.

FIG. 6 is a schematic structural diagram of a cold source circulation system.

FIG. 7 is a schematic structural diagram of a first heat exchanger.

FIG. 8 is a schematic structural diagram of a second heat exchanger.

FIG. 9 is a schematic structural diagram of a liquid supply circulation system.

FIG. 10 is a schematic structural diagram of a temperature regulation module.

FIG. 11 is a schematic structural diagram of a cold plate liquid supply module.

FIG. 12 is a schematic structural diagram of a cold plate liquid return module.

FIG. 13 is a schematic structural diagram of an isolated circulation system.

FIG. 14 is a schematic structural diagram of an isolated liquid supply module.

FIG. 15 is a schematic structural diagram of an isolated liquid return module.

FIG. 16 is a schematic structural diagram of a liquid replenishment tank.

### DETAILED DESCRIPTION

Technical solutions in embodiments of the present application are clearly and completely described below with reference to the accompanying drawings in the embodiments of the present application. Apparently, the described embodiments are merely some rather than all of the embodiments of the present application. All other embodiments obtained by a person of ordinary skill in the art based on the embodiments of the present application without creative efforts shall fall within the protection scope of the present application.

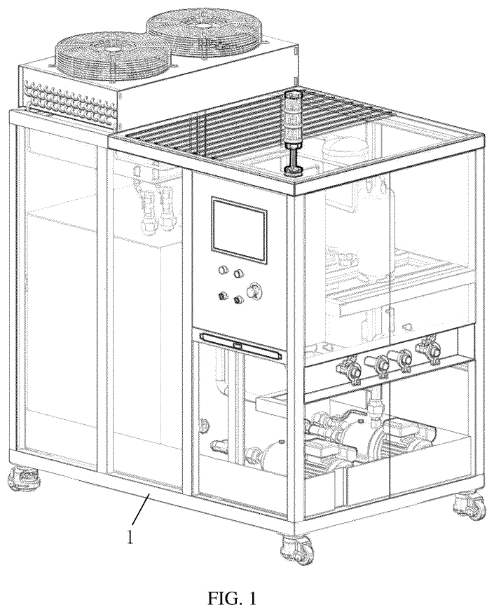

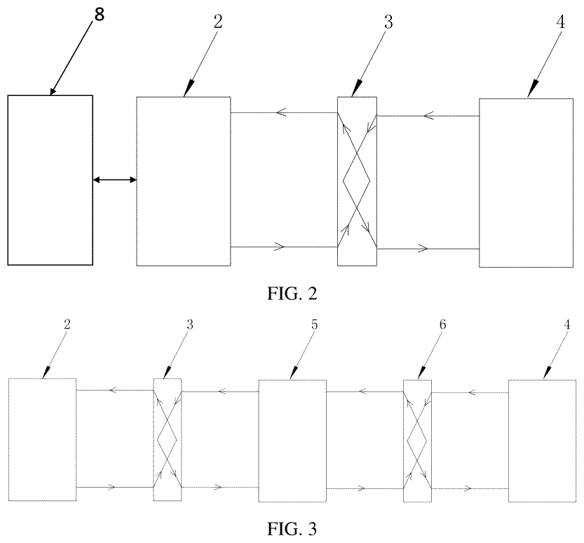

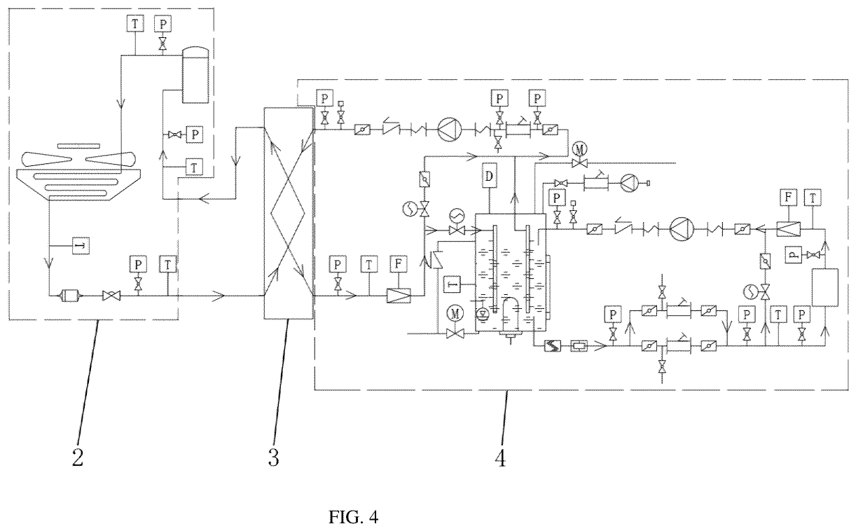

Referring to FIG. 1, FIG. 2, and FIG. 4, FIG. 1 is a schematic diagram of an overall structure of a specific implementation according to the present application, and FIG. 2 is a schematic diagram of a system architecture in a first specific implementation according to the present application, and FIG. 4 is a schematic diagram of specific system modules of the system architecture shown in FIG. 2.

In a specific implementation provided by the present application, a liquid cooling device with self-configuring cold and heat sources mainly includes a cabinet 1, a cold source circulation system 2, a first heat exchanger 3, a liquid supply circulation system 4, and a controller 8.

The cabinet 1 is a main component of the device, and is mainly configured to install and accommodate other components of the device, and the cold source circulation system 2, the first heat exchanger 3, the liquid supply circulation system 4, and the controller 8 are all integrated on the cabinet 1 to achieve the integrated installation, whereby a simple cold-plate liquid cooling environment is constructed in the cabinet 1.

The cold source circulation system 2 is disposed on the cabinet 1 and is mainly configured to drive a refrigerant to circularly flow along a preset path and perform a cooling operation on the refrigerant during circular flow of the refrigerant, to cool the refrigerant and form a low-temperature medium that is mainly configured to provide a cold source for the constructed cold-plate liquid cooling environment.

The liquid supply circulation system 4 is disposed on the cabinet 1 and is mainly configured to drive cooling liquid to circularly flow along a preset path, and enable the cooling liquid to flow through a cold plate during circular flow of the cooling liquid, where the cold plate is kept in tight contact with a load 7 (a heating element such as a server component), whereby the cooling liquid can absorb heat of the load 7 through the cold plate, to implement heat dissipation for the load 7.

The first heat exchanger 3 is also disposed on the cabinet 1, specifically connected between the cold source circulation system 2 and the liquid supply circulation system 4, and mainly configured to facilitate heat exchange between the cold source circulation system 2 and the liquid supply circulation system 4. To be specific, when the cooled refrigerant (the low-temperature medium) flows through the first heat exchanger 3 during circular flow, the cooling liquid (a high-temperature medium) absorbing the heat of the load 7 also flows through the first heat exchanger 3 during circular flow, whereby the refrigerant exchanges heat with the cooling liquid in the first heat exchanger 3, the cooling liquid absorbing the heat of the load 7 transfers the absorbed heat to the refrigerant, and the cooled cooling liquid continues to flow circularly and absorb the heat of the load 7 again, and this process is repeated.

The controller 8 is at least kept in signal connection with the cold source circulation system 2, and is mainly configured to control an operation state of the cold source circulation system 2 according to an actual heat dissipation requirement (i.e., a cooling capacity demand) of the load 7, for example, controlling parameters of the refrigerant of the cold source circulation system 2 such as temperature, flow rate, and the pressure, whereby the cooling capacity of the refrigerant in the cold source circulation system 2 during each heat exchange with the cooling liquid in the liquid supply circulation system 4 is closely equivalent to the heat absorbed by the cooling liquid, thereby ensuring that the cooling capacity provided by the cold source circulation system 2 meets the actual heat dissipation requirement of the load 7.

In this way, the refrigerant is cooled by the cold source circulation system 2 and driven to circularly flow, whereby the supply of the cold source can be achieved; the cooling liquid is driven by the liquid supply circulation system 4 to circularly flow and flow through the cold plate, whereby the cold-plate liquid cooling can be implemented for the load 7; a heat exchange space is provided by the first heat exchanger 3, whereby the cooling liquid in the liquid supply circulation system 4 can exchange the heat of the load 7 with the refrigerant in the cold source circulation system 2, thereby continuously implementing the load-plate liquid cooling and heat dissipation for the load 7; the cold source circulation system 2, the first heat exchanger 3, and the liquid supply circulation system 4 are integrated on the cabinet 1 to achieve an integrated design, collectively forming a simple cold-plate liquid cooling environment with the cabinet 1 serving as a structural platform, thereby achieving an engineering-free design of the cold-plate liquid cooling environment, requiring no additional outdoor chillers, cooling towers, primary/secondary cooling liquid circulation pipelines, or power supplies in scenes such as an air-cooled data center, also avoiding the need of engineered modification for a heat dissipation environment of the server, greatly reducing the configuration cost, configuration difficulty, and configuration period, and facilitating popularization in the air-cooled data centers and similar settings; and at the same time, the controller 8 controls the operation state of the cold source circulation system 2 according to the heat dissipation requirement of the load 7, whereby the cooling capacity provided by the cold source circulation system 2 is ensured to match the actual heat dissipation requirement of the load 7 as far as possible, thereby avoiding the problems such as insufficient cooling capacity or excessive cooling capacity.

In conclusion, the liquid cooling device with self-configuring cold and heat sources provided by the present embodiment can achieve an engineer-free design for cold-plate liquid cooling environment construction, and facilitate convenient and low-cost cold-plate liquid cooling for the servers and accurate control of cooling capacity supply.

Furthermore, the liquid cooling device with self-configuring cold and heat sources provided in the present embodiment can be better suitable for the liquid cooling upgrading modification of the existing air-cooled data centers, requires no large-scale construction, modification, or shut-down of existing server rooms, and is particularly suitable for scenes requiring small-scale liquid cooling and heat dissipation test, such as education, research, universities, and laboratories. Moreover, limitations of the conventional cold-plate liquid cooling environment that is immovable and has low reusability are overcome. Thanks to the fully integrated design, the liquid cooling device with self-configuring cold and heat sources can be easily moved and redeployed across different locations according to specific application scenes.

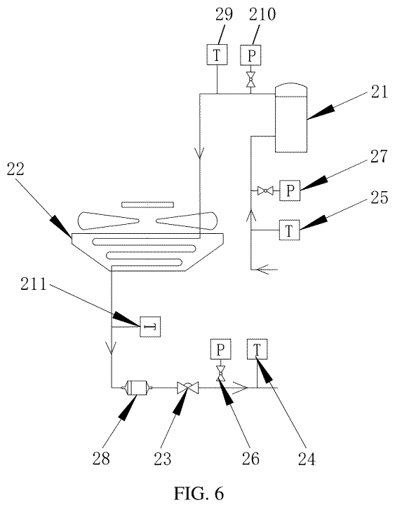

As shown in FIG. 6, FIG. 6 is a schematic structural diagram of a cold source circulation system 2.

In a specific embodiment of the cold source circulation system 2, the cold source circulation system 2 mainly includes a compressor 21, a condenser 22, an expansion valve 23, and an evaporator (an evaporation heat exchange pipeline 31 of a first heat exchanger 3), and a principal operation principle of the cold source circulation system is a refrigeration principle of an air conditioner, that is, a physical phenomenon of heat absorption in a refrigerant gasification process and heat release in a liquefaction process is utilized to achieve a refrigeration function, to take away the heat generated by the load 7 and discharge the heat into an external environment.

An outlet of the compressor 21 is in communication with an inlet of the condenser 22, an outlet of the condenser 22 is in communication with an inlet of the expansion valve 23, an outlet of the expansion valve 23 is in communication with an inlet of the evaporation heat exchange pipeline 31 of the first heat exchanger 3, and an outlet of the evaporation heat exchange pipeline 31 of the first heat exchanger 3 is in communication with an inlet of the compressor 21. The compressor 21 is mainly configured to compress the low-temperature and low-pressure refrigerant after heat exchange into a high-temperature and high-pressure gas and provide a driving force for refrigeration cycles, thereby achieving the refrigeration cycle of compression, condensation, expansion, and evaporation in sequence; and moreover, the compressor can automatically adjust an operation state under the control of the controller 8 to achieve energy conservation and efficiency improvement.

A main function of the condenser 22 is to discharge the heat from the high-temperature and high-pressure refrigerant gas processed by the compressor 21 into the external environment through a medium such as air or cooling water, and transform the refrigerant from a high-temperature and high-pressure gaseous state into a medium-temperature and high-pressure liquid state, thereby completing the heat dissipation and cooling operation of the refrigerant.

The expansion valve 23 is mainly configured to throttle the medium-temperature and high-pressure liquid refrigerant into low-temperature and low-pressure wet vapor, and then the refrigerant absorbs heat in the evaporation heat exchange pipeline 31 of the first heat exchanger 3, thereby achieving a cooling and heat dissipation effect. At the same time, the expansion valve 23 can control a flow rate of the refrigerant entering the first heat exchanger 3, ensuring that all refrigerant entering the compressor 21 is gaseous refrigerant. The expansion valve 23 can also control a flow rate of the valve according to the change of a superheat degree at the end of the first heat exchanger 3, thereby preventing insufficient utilization of an evaporation area and compressor slugging phenomenon.

Furthermore, a first temperature sensor 24, a second temperature sensor 25, a first pressure sensor 26, and a second pressure sensor 27 are additionally provided in the present embodiment. The first temperature sensor 24 is mainly configured to detect the inlet temperature of the evaporation heat exchange pipeline 31 and feed a detected value back to the controller 8. The second temperature sensor 25 is mainly configured to detect the outlet temperature of the evaporation heat exchange pipeline 31 and feed a detected value back to the controller 8. The first pressure sensor 26 is mainly configured to detect the inlet pressure of the evaporation heat exchange pipeline 31 and feed a detected value back to the controller 8. The second pressure sensor 27 is mainly configured to detect the outlet pressure of the evaporation heat exchange pipeline 31 and feed a detected value back to the controller 8. The controller 8 can determine a heat exchange capacity of the first heat exchanger 3 according to detection data of the first temperature sensor 24, the second temperature sensor 25, the first pressure sensor 26, and the second pressure sensor 27, further determines a current heat dissipation requirement of the load 7, and finally controls the operation state of the compressor 21 according to the current heat dissipation requirement of the load 7 to ensure that the heat transferred from the load 7 to the cooling liquid is equivalent to the heat released from the cooling liquid to the refrigerant, thereby avoiding over-cooling or over-heating of the cooling liquid, and maintaining a constant-temperature circulation mode as far as possible. For example, when it is determined that the heat exchange capacity is relatively high, the power of the compressor 21 is increased accordingly, and vice versa.

A filter dehumidifier 28 is additionally provided in the present embodiment. Specifically, the filter dehumidifier 28 is communicated between the outlet of the condenser 22 and the inlet of the expansion valve 23 and is mainly configured to filter water and impurities in the refrigerant. Specifically, a molecular sieve structure is employed inside the filter dehumidifier 28 to purify the system, thereby preventing the problems such as pipeline blockage caused by excessively high water content and impurities of the refrigerant, and effectively reducing the occurrence probabilities of system failure, pipeline damage, and the like.

A third temperature sensor 29, a third pressure sensor 210, and a fourth temperature sensor 211 are additionally provided in the present embodiment. Specifically, the third temperature sensor 29 is configured to detect refrigerant temperature at the outlet of the compressor 21, the third pressure sensor 210 is configured to detect refrigerant pressure at the outlet of the compressor 21, and the first pressure sensor 26, the second pressure sensor 27, and the third pressure sensor 210 are each integrated with an on-off valve, whereby calibration and replacement of the pressure sensors can be implemented without shutting down the system. The fourth temperature sensor 211 is configured to detect the temperature of refrigerant at the outlet of the condenser 22. Similarly, detected values of all the third temperature sensor 29, the third pressure sensor 210, and the fourth temperature sensor 211 are fed back to the controller 8, whereby the controller 8 determines whether the operation state of the cold source circulation system 2 is normal according to a specific utilization requirement, and adjusts the operation state of the whole cold source circulation system 2 according to the specific heat dissipation requirement of the load 7.

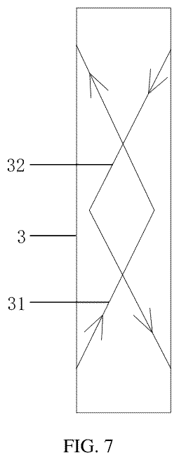

As shown in FIG. 7, FIG. 7 is a schematic structural diagram of a first heat exchanger 3.

In a specific embodiment of the first heat exchanger 3, two channels, i.e., an evaporation heat exchange pipeline 31 and a condensation heat exchange pipeline 32 are provided in the first heat exchanger 3. The evaporation heat exchange pipeline 31 is mainly configured to facilitate the flow of refrigerant in the cold source circulation system 2, to achieve heat-absorbing evaporation. The condensation heat exchange pipeline 32 is mainly configured to facilitate the flow of the cooling liquid in the liquid supply circulation system 4 or the flow of an intermediate heat-conducting medium in an isolated circulation system 5, to achieve heat-release condensation. Generally, the first heat exchanger 3 specifically employs a brazing-type integrated design.

As shown in FIG. 9, FIG. 9 is a schematic structural diagram of a liquid supply circulation system 4.

In a specific embodiment of the liquid supply circulation system 4, the liquid supply circulation system 4 mainly includes a temperature regulation module 41, a cold plate liquid supply module 42, and a cold plate liquid return module 43. An inlet of the temperature regulation module 41 is in communication with an outlet of the condensation heat exchange pipeline 32 of the heat exchanger 3, and mainly configured to adjust the temperature of the cooling liquid, to supply constant-temperature liquid to the load 7; and the temperature regulation module 41 is in signal connection with the controller 8, to control an operation state of the temperature regulation module 41 according to the heat dissipation requirement of the load 7. An inlet of the cold plate liquid supply module 42 is in communication with an outlet of the temperature regulation module 41, and an outlet of the cold plate liquid supply module 42 is in communication with the inlet of the load 7, and mainly configured to lead out the constant-temperature cooling liquid in the temperature regulation module 41, to implement liquid supply and heat dissipation for the load 7. An inlet of the cold plate liquid return module 43 is in communication with the outlet of the load 7, an outlet of the cold plate liquid return module 43 is in communication with an inlet of the condensation heat exchange pipeline 32 of the first heat exchanger 3 and is mainly configured to drive the cooling liquid to circularly flow, whereby the heat of the load 7 is transferred to the condensation heat exchange pipeline 32 of the first heat exchanger 3 through the cooling liquid, and then transferred into the refrigerant in the cold source circulation system 2, and finally the cooling liquid flows back to the temperature regulation module 41, thus forming a cycle.

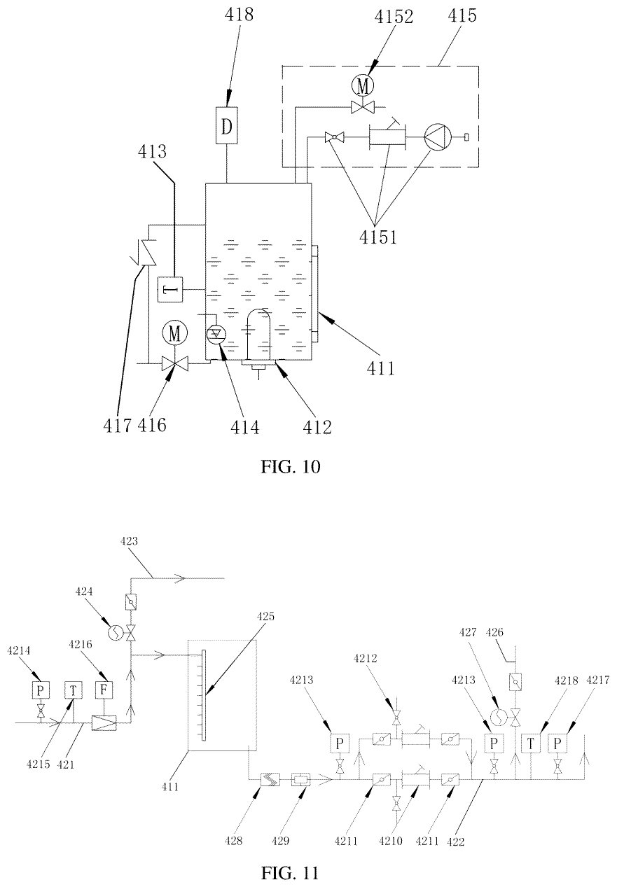

As shown in FIG. 10, FIG. 10 is a schematic structural diagram of a temperature regulation module 41.

In a specific embodiment of the temperature regulation module 41, the temperature regulation module 41 mainly includes a temperature regulation water storage tank 411, a heater 412, and a water tank temperature sensor 413.

The temperature regulation water storage tank 411 specifically employs a stainless steel integrated welding molding process, which can effectively protect the quality of the cooling liquid. The temperature regulation water storage tank is mainly configured to temporarily store a specific amount of cooling liquid. The heater 412 is disposed in the temperature regulation water storage tank 411 and is mainly configured to heat the cooling liquid in the temperature regulation water storage tank 411. When the temperature of the cooling liquid is less than the temperature required by the server, the cooling liquid is automatically heated, thereby preventing issues such as condensation in the server liquid cooling pipelines or failure to meet the required temperature of the cooling liquid due to the excessively low temperature of the cooling liquid. Naturally, if the temperature of the cooling liquid in the temperature regulation water storage tank 411 is desired to be lowered, only the heater 412 needs to be closed; and as the cooling liquid after heat release continues to flow into the temperature regulation water storage tank 411, the temperature of the cooling liquid may decrease rapidly. The water tank temperature sensor 413 is disposed in the temperature regulation water storage tank 411 and is mainly configured to detect the temperature of the cooling liquid in the temperature regulation water storage tank 411; moreover, the water tank temperature sensor 413 and the heater 412 are both in signal connection with the controller 8, whereby the controller 8 controls an operation state of the heater 412 according to a detected value of the water tank temperature sensor 413 and the heat dissipation requirement of the load 7, to ensure that the temperature of the cooling liquid in the temperature regulation water storage tank 411 is kept within a constant range matching the cooling capacity demand of the load 7.

To control a temporary storage amount of the cooling liquid in the temperature regulation water storage tank 411, a liquid level meter 414, a liquid replenishment mechanism 415, and a liquid discharge mechanism 416 are additionally provided in the present embodiment.

The liquid level meter 414 is disposed in the temperature regulation water storage tank 411 and is mainly configured to detect a liquid level of the cooling liquid that is temporarily stored in the temperature regulation water storage tank 411 in real time, and is in signal connection with the controller 8. The liquid level meter 414 can display a cooling liquid capacity in the temperature regulation water storage tank 411 in real time on a display screen of the cabinet 1, and issues an alarm signal and feeds back to the controller 8 when the level of the cooling liquid is too high or the cooling liquid capacity is insufficient, whereby the controller 8 automatically controls operation states of the liquid replenishment mechanism 415 and the liquid discharge mechanism 416 for timely liquid replenishment or liquid discharge. At the same time, the temperature regulation water storage tank 411 may also be provided with a liquid level visual window to observe the liquid level.

The liquid replenishment mechanism 415 is in communication with the temperature regulation water storage tank 411, and specifically includes an automatic liquid replenishment assembly 4151 and a manual liquid replenishment assembly 4152. The manual liquid replenishment assembly 4152 mainly includes a manual liquid replenishment on-off valve, a liquid replenishment filter 4210, and a water tank liquid replenishment pump, where one end of the manual liquid replenishment assembly 4152 is connected to an upper end of the temperature regulation water storage tank 411, the other end is connected to an external unpressurized server cooling liquid container; and when the temperature regulation water storage tank 411 requires manual liquid replenishment, an operator manually opens the manual liquid replenishment on-off valve and activates the water tank liquid replenishment pump for liquid replenishment. At the same time, the liquid replenishment filter 4210 can filter and clean the replenished cooling liquid, thereby preventing impurities in the cooling liquid from entering the temperature regulation water storage tank 411. One end of the automatic liquid replenishment assembly 4151 is connected to an upper end of the temperature regulation water storage tank 411, and the other end is connected with an external pressurized cooling liquid delivery pipeline that is provided with an on-off electromagnetic valve. When the temperature regulation water storage tank 411 outputs a liquid replenishment requirement, the on-off electromagnetic valve is automatically opened, and the cooling liquid is automatically delivered into the temperature regulation water storage tank 411 by using the external pressurized cooling liquid. After the liquid replenishment is completed, the on-off electromagnetic valve is closed automatically.

One end of the liquid discharge mechanism 416 is in communication with the lower end of the temperature regulation water storage tank 411, mainly configured to implement a liquid discharge operation of the temperature regulation water storage tank 411, and provided with an electric on-off valve; and when the temperature regulation water storage tank 411 requires a liquid discharge operation, the electric on-off valve is automatically opened under the control of the controller 8 to automatically discharge the cooling liquid.

To prevent overflow caused by excessive cooling liquid in the temperature regulation water storage tank 411, an overflow valve 417 is additionally provided in the present embodiment. Specifically, an inlet of the overflow valve 417 is connected to a preset position (i.e., a maximum safety water level position of the temperature regulation water storage tank 411) on the upper end of the temperature regulation water storage tank 411, an outlet is directly connected with the exterior, and the overflow valve is mainly configured to implement safety overflow. When the cooling liquid in the temperature regulation water storage tank 411 reaches a maximum safety water level, the excess cooling liquid is automatically discharged to the exterior through the overflow valve 417, preventing system failure caused by excessive water.

To ensure stable pressure in the temperature regulation water storage tank 411, a pressure stabilizer 418 is additionally provided in the present embodiment. Specifically, the pressure stabilizer 418 is in communication with the top of the temperature regulation water storage tank 411 through a static pressure pipeline, and is mainly configured to stabilize the pressure in the temperature regulation water storage tank 411. Specifically, when the pressure in the temperature regulation water storage tank 411 changes, the pressure stabilizer 418 can automatically utilize external atmospheric pressure to perform pressure stabilization according to the change of the pressure. At the same time, the top of the pressure stabilizer 418 is provided with a dust-proof end cover, preventing external particles from entering the temperature regulation water storage tank 411 and polluting the cooling liquid.

As shown in FIG. 11, FIG. 11 is a schematic structural diagram of a cold plate liquid supply module 42.

In a specific embodiment of the cold plate liquid supply module 42, the cold plate liquid supply module 42 mainly includes a distal liquid inlet pipe 421 and a proximal liquid inlet pipe 422. An inlet of the distal liquid inlet pipe 421 is in communication with the outlet of the condensation heat exchange pipeline 32 of the first heat exchanger 3, an outlet of the distal liquid inlet pipe 421 is in communication with (an upper end of) the temperature regulation water storage tank 411. Specifically, the distal liquid inlet pipe 421 is mainly configured to convey the cooling liquid exchanging heat in the first heat exchanger 3 (or a second heat exchanger 6) into the temperature regulation water storage tank 411 to regulate and control the temperature of the cooling liquid. An inlet of the proximal liquid inlet pipe 422 is in communication with (a lower end of) the temperature regulation water storage tank 411, and an outlet of the proximal liquid inlet pipe 422 is in communication with the inlet of the load 7. Specifically, the proximal liquid inlet pipe 422 is mainly configured to convey the cooling liquid that is approximately at a constant temperature in the temperature regulation water storage tank 411 into the load 7, to perform cold-plate liquid cooling for the load 7.

Considering that the cooling capacity of the cooling liquid is prone to surplus when the heat generated by the load 7 is relatively small, the heater 412 inside the temperature regulation water storage tank 411 generally needs to be activated to heat the cooling liquid; and to alleviate a load of the heater 412, and reduce the energy consumption, a distal bypass liquid inlet pipe 423 and a distal bypass regulation valve 424 are additionally provided in the present embodiment. An inlet of the distal bypass liquid inlet pipe 423 is in communication with the distal liquid inlet pipe 421, and an outlet of the distal bypass liquid inlet pipe 423 is in communication with the cold plate liquid return module 43. The distal bypass regulation valve 424 is disposed on the distal bypass liquid inlet pipe 423, and an openness of the distal bypass regulation valve is adjustable, whereby a flow rate of the cooling liquid entering the distal bypass liquid inlet pipe 423 can be controlled from the distal liquid inlet pipe 421. Meanwhile, the distal bypass regulation valve 424 is in signal connection with the controller 8; the distal bypass regulation valve 424 is kept in a closed state under normal conditions, and all cooling liquid enters the temperature regulation water storage tank 411 through the distal liquid inlet pipe 421; when a detected value of the water tank temperature sensor 413 is less than a preset threshold, the current cooling capacity in the temperature regulation water storage tank 411 is excessive, and then the distal bypass regulation valve 424 is opened, whereby a portion of the cooling liquid directly enters the cold plate liquid return module 43 through the distal bypass liquid inlet pipe 423, and no longer enters the temperature regulation water storage tank 411, and the temperature of the cooling liquid in the temperature regulation water storage tank 411 can be rapidly increased to a preset temperature under a heating effect of the heater 412.

Considering that the cooling liquid entering the temperature regulation water storage tank 411 from the distal liquid inlet pipe 421 flows down gradually from the top of the temperature regulation water storage tank 411 to possibly lead to uneven temperature of the cooling liquid at each layer in the temperature regulation water storage tank 411, a water distributor 425 is additionally provided in the present embodiment. Specifically, the water distributor 425 is disposed in the temperature regulation water storage tank 411, an inlet of the water distributor 425 is in communication with the outlet of the distal liquid inlet pipe 421, the water distributor 425 is provided with a plurality of outlets, and the outlets are distributed along a height direction of the temperature regulation water storage tank 411. With the configuration, after the cooling liquid enters the water distributor 425, the cooling liquid may flow out from the outlets of the water distributor 425 simultaneously, and the outlets are distributed at different heights of the temperature regulation water storage tank 411 respectively, whereby the cooling liquid can be uniformly divided into a plurality of portions that may simultaneously flow to different heights of the temperature regulation water storage tank 411, thereby ensuring that the temperature of the cooling liquid at various layers in the temperature regulation water storage tank 411 is prone to uniform.

The proximal liquid inlet pipe 422 is similar to the distal liquid inlet pipe 421. When the heat generated by the load 7 is relatively small, the cooling capacity of the cooling liquid is prone to surplus. If all cooling liquid passing through the proximal liquid inlet pipe 422 enters the load 7, over-cooling of the load 7 may be caused, and a normal operation of the load 7 may be affected. In view of this, a proximal bypass liquid inlet pipe 426 and a proximal bypass regulation valve 427 are additionally provided in the present embodiment.

An inlet of the proximal bypass liquid inlet pipe 426 is in communication with the proximal liquid inlet pipe 422, and an outlet of the proximal bypass liquid inlet pipe 426 is in communication with the cold plate liquid return module 43. The proximal bypass regulation valve 427 is disposed on the proximal bypass liquid inlet pipe 426, and an openness of the proximal bypass regulation valve is adjustable, whereby a flow rate of cooling liquid entering the proximal bypass liquid inlet pipe 426 can be controlled from the proximal liquid inlet pipe 422. At the same time, the proximal bypass regulation valve 427 is in signal connection with the controller 8, and the proximal bypass regulation valve 427 is kept in a closed state under normal conditions, whereby all cooling liquid enters the load 7 through the proximal liquid inlet pipe 422. When a cooling liquid demand of the load 7 is less than a minimum flow rate of returned liquid of the cold plate liquid return module 43, the current heat generated by the load 7 is relatively small. In this case, the proximal bypass regulation valve 427 is opened, allowing a portion of the cooling liquid to flow directly into the cold plate liquid return module 43 through the proximal bypass liquid inlet pipe 426, without entering the load 7, thereby preventing the load 7 from being overcooled.

To implement disinfection for the cooling liquid, a disinfection component 428 is additionally provided in the present embodiment. Specifically, the disinfection component 428 is disposed on the proximal liquid inlet pipe 422 and may specifically employ an ultraviolet disinfection device that mainly utilizes an ultraviolet disinfection technology to actively kill microorganisms (such as bacteria and viruses) in the cooling liquid, thereby preventing pollution of the cooling liquid caused by excessive microorganisms in the cooling liquid, and preventing corrosive damage of the components.

To achieve intuitive monitoring for a circulation state of the cooling liquid, a monitoring component 429 is additionally provided in the present embodiment. Specifically, the monitoring component 429 is disposed on the proximal liquid inlet pipe 422, and may specifically employ transparent glass that is mainly configured for an operator to monitor and view a circulation state of the cooling liquid, such as turbidity of water, impurities in the water, and amount of bubbles.

To filter and sample the cooling liquid, filters 4210, first on-off valves 4211, and water quality sampling valves 4212 are additionally provided in the present embodiment. At least two filters 4210 are provided. The present embodiment is described by using two filters as an example. The two filters 4210 are parallel connected on the proximal liquid inlet pipe 422, and may specifically employ a stainless steel washable filter element design, whereby particulate matters in the cooling liquid can be removed, and the water quality state of the cooling liquid can be ensured to meet use requirements of the cooling liquid. At the same time, the parallel configuration of the two filters 4210 on the proximal liquid inlet pipe 422 enables a “one-in-operation, one-on-standby” dual-filter pipeline mode, thereby ensuring uninterrupted system operation when one filter pipeline fails or the filter element requires maintenance, such as cleaning or replacement. The first on-off valves 4211 are disposed respectively at inlet and outlet ends of the filters 4210, to separately control the on-off state of the inlet and outlet ends of the filters 4210. The water quality sampling valves 4212 are respectively in communication with the inlets of the filters 4210, to sample and discharge the cooling liquid. With the configuration, when the filter element of one filter 4210 requires maintenance, only the two first on-off valves 4211 corresponding to the filter 4210 need to be closed, and then the filter element of the filter 4210 may be maintained, whereby the other filter 4210 is not affected, and may filter the cooling liquid normally, thereby washing and replacing the filter element of the filter 4210 and implementing pipeline maintenance of the filter in a non-shut-down state. Furthermore, the operator may also conveniently sample the cooling liquid through the water quality sampling valves 4212, enabling collection and sending of samples for analysis without shutting down the system.

Further, to automatically detect an operation state of each filter 4210, monitoring pressure sensors 4213 are additionally provided in the present embodiment. Specifically, two monitoring pressure sensors 4213 are provided, and both are disposed on the proximal liquid inlet pipe 422 and located respectively at the inlet and outlet ends of the filters 4210, and the two monitoring pressure sensors collectively form a filter element state monitoring unit of the filter 4210; a filter element state of the filter 4210 is mainly determined and monitored by comparing a difference of pressure at the inlet and outlet of the filter 4210; and when the difference of detected values of the monitoring pressure sensors 4213 at both ends is greater than a preset threshold, the controller 8 issues a filter element maintenance alarm, whereby the operator overhauls and replaces the filter element in time.

Furthermore, to accurately detect an overall operation state of the cold plate liquid supply module 42, a fourth pressure sensor 4214, a fifth temperature sensor 4215, a first flow meter 4216, a fifth pressure sensor 4217, and a sixth temperature sensor 4218 are additionally provided in the present embodiment.

The fourth pressure sensor 4214, the fifth temperature sensor 4215, and the first flow meter 4216 collectively form a cooling liquid state monitoring unit in the distal liquid inlet pipe 421, which can read and output pressure, temperature, and flow rate data of the low-temperature cooling liquid after heat exchange, and simultaneously transmit the data to the controller 8, whereby the controller 8 adjusts relevant operation parameters of the device in time according to the feedback data and the operation conditions.

The fifth pressure sensor 4217 and the sixth temperature sensor 4218 are respectively configured to detect the pressure of the cooling liquid and read and monitor the temperature of the cooling liquid at the inlet of the load 7, to ensure that parameters of the cooling liquid entering the load 7 meet the current actual heat dissipation requirement of the load 7. Meanwhile, the fifth pressure sensor 4217 and the seventh pressure sensor 4310 further form key components of a system pressure-difference operation mode.

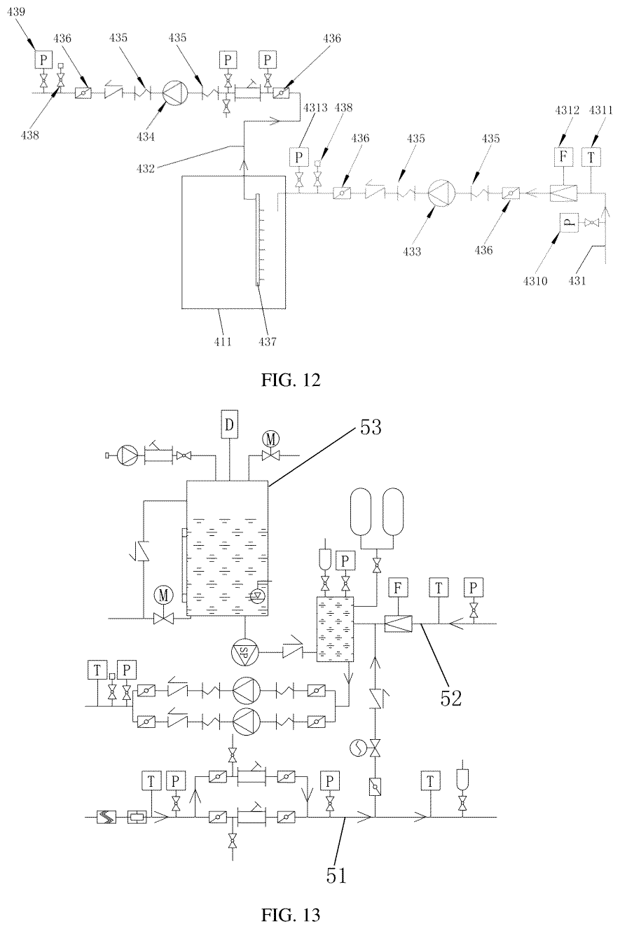

As shown in FIG. 12, FIG. 12 is a schematic structural diagram of a cold plate liquid return module 43.

In a specific embodiment of the cold plate liquid return module 43, the cold plate liquid return module 43 mainly includes a proximal liquid return pipe 431, a distal liquid return pipe 432, a proximal circulation pump 433, and a distal circulation pump 434.

An inlet of the proximal liquid return pipe 431 is in communication with the outlet of the load 7, and an outlet of the proximal liquid return pipe 431 is in communication with the temperature regulation water storage tank 411; and the proximal liquid return pipe is mainly configured to lead out the cooling liquid that absorbs the heat of the load 7, and guide the cooling liquid to re-enter the temperature regulation water storage tank 411, whereby the temperature regulation water storage tank 411 can utilize the heat of the cooling liquid to heat the excessively low-temperature cooling liquid, thereby reducing energy consumption of the heater 412.

An inlet of the distal liquid return pipe 432 is in communication with the temperature regulation water storage tank 411, and an outlet of the distal liquid return pipe 432 is in communication with the inlet of the condensation heat exchange pipeline 32 of the first heat exchanger 3 (or the heat release pipeline 62 of the second heat exchanger 6); and the distal liquid return pipe is mainly configured to guide the cooling liquid that absorbs the heat of the load 7 and passes through the temperature regulation water storage tank 411 into the first heat exchanger 3 (or the second heat exchanger 6), to transfer all the remaining heat to the refrigerant in the cold source circulation system 2, thereby re-cooling the cooling liquid, and enabling the cooling liquid to flow back into the distal liquid inlet pipe 421.

The proximal circulation pump 433 is disposed on the proximal liquid return pipe 431, and mainly configured to drive the cooling liquid to flow into the temperature regulation water storage tank 411 from the outlet of the load 7. The distal circulation pump 434 is disposed on the distal liquid return pipe 432, and mainly configured to drive the cooling liquid to flow into the inlet of the condensation heat exchange pipeline 32 of the first heat exchanger 3 (or the heat release pipeline 62 of the second heat exchanger 6) from the temperature regulation water storage tank 411.

Considering that the proximal circulation pump 433 may be difficult to align accurately with the proximal liquid return pipe 431 due to an installation error or other factors, vibration damping pipes 435 are additionally provided in the present embodiment. Specifically, the vibration damping pipes 435 are simultaneously disposed at the inlet and outlet ends of the proximal circulation pump 433, the vibration damping pipe 435 is elastic and capable of elastic deformation; and the vibration damping pipe is mainly configured to eliminate the installation error when the proximal circulation pump 433 is connected with the proximal liquid return pipe 431, thereby enhancing the installation error-tolerant rate, and facilitating the installation. At the same time, when vibration generated by the operation of the proximal circulation pump 433 is transferred to the vibration damping pipes 435 at both ends, vibration energy may be absorbed by the elastic deformation of the vibration damping pipes 435, thereby alleviating shock vibration to the whole proximal liquid return pipe 431, and improving the operation stability of the proximal circulation pump 433.

Similarly, for the distal circulation pump 434, the vibration damping pipes 435 may also be disposed at both the inlet and outlet ends of the distal circulation pump 434. For an operation principle and beneficial effects, refer to the previous paragraph. Details are not described herein again.

Further, in the present embodiment, second on-off valves 436 are respectively disposed at the inlet and outlet ends of the proximal circulation pump 433. Specifically, the second on-off valves 436 are mainly configured to control the on-off states of both the inlet and outlet ends of the proximal circulation pump 433, and when the proximal circulation pump 433 needs to be overhauled, the proximal circulation pump 433 can be separated from the proximal liquid return pipe 431. With the configuration, subsequent maintenance and repair operations for the proximal liquid return pipe 431 may be performed simply by discharging the cooling liquid from an area, located in the proximal circulation pump 433, of the proximal liquid return pipe 431, thereby avoiding waste of manpower and resources caused by large-scale liquid discharge, and preventing an increase in maintenance difficulty and cost.

Similarly, for the distal circulation pump 434, the second on-off valves 436 may also be disposed at both the inlet and outlet ends of the distal circulation pump 434. For the operation principle and beneficial effects, refer to the previous paragraph, and details are not described herein again.

Additionally, considering that in the aforementioned embodiment, the water distributor 425 is installed in the temperature regulating water storage tank 411 to achieve uniform cooling liquid discharge and temperature consistency, similarly, in the present embodiment, a water collector 437 is also disposed in the temperature regulating water storage tank 411. Specifically, the water collector 437 is disposed in the temperature regulation water storage tank 411, and is generally far away from the water distributor 425, for example, the water collector and the water distributor are separately located at two sides of the temperature regulation water storage tank 411. An outlet of the water collector 437 is in communication with the inlet of the distal liquid return pipe 432, and the water collector 437 is provided with a plurality of inlets, the inlets are distributed along a length direction of the water collector 437, i.e., along a height direction of the temperature regulation water storage tank 411, which is mainly configured to enable the cooling liquid at various levels in the temperature regulation water storage tank 411 to be pumped out by the distal circulation pump 434 into the distal liquid return tube 432, thereby preventing the withdrawal of the cooling liquid only from local areas of the temperature regulation water storage tank 411. Consequently, the flow efficiency of the cooling liquid inside the temperature regulation water storage tank 411 is enhanced; and moreover, in cooperation with the water distributor 425, the water collector further enhances the temperature uniformity of the cooling liquid across different layers in the temperature regulation water storage tank 411.

To prevent overpressure rupture of the distal liquid return pipe 432, a safety valve 438 is additionally provided in the present embodiment. Specifically, the safety valve 438 is disposed in an outlet area of the distal liquid return pipe 432, and mainly configured to automatically release the pressure when overpressure of the pipeline is caused by the blockage of the distal liquid return pipe 432, thereby preventing the pipeline rupture and damage of pumping apparatuses caused by the overpressure of the pipeline. The safety valve 438 may also be disposed in an outlet area of the proximal liquid return pipe 431, and an operation principle and beneficial effects are the same and not repeated here.

Furthermore, to accurately detect an overall operation state of the cold plate liquid return module 43, a sixth pressure sensor 439, a seventh pressure sensor 4310, a seventh temperature sensor 4311, a second flow meter 4312, and an eighth pressure sensor 4313 are additionally provided in the present embodiment.

The sixth pressure sensor 439 is mainly configured to read and output the pressure at the outlet of the distal liquid return pipe 432, the controller 8 determines whether the distal circulation pump 434 can be operated normally according to the pressure value, and determines the operation state of the first heat exchanger 3 (or the second heat exchanger 6) by comparing with the value measured by the fourth pressure sensor 4214.

The seventh pressure sensor 4310 is mainly configured to read and output the pressure at the outlet end of the load 7, and feed the detected value back to the controller 8, the controller 8 compares the current pressure value with the detected value of the fifth pressure sensor 4217 to determine whether the current system state can meet the actual application requirement of the load 7, whereby the controller 8 enables the system to be operated in a pressure-difference control mode.

The seventh temperature sensor 4311 is mainly configured to detect the temperature of the cooling liquid that absorbs the heat of the load 7, and feed a detected value back to the controller 8. The controller 8 then compares the current temperature value with the detected value of the sixth temperature sensor 4218 to determine whether the current system state can meet the actual operation requirements.

The second flow meter 4312 is mainly configured to detect a flow rate of the cooling liquid in the proximal liquid return pipe 431, and feed a detected value back to the controller 8, whereby the controller 8 monitors the flow rate of the cooling liquid in real time and makes relevant adjustments according to actual requirements.

The eighth pressure sensor 4313 is mainly configured to detect the pressure at the outlet of the proximal liquid return pipe 431, and feed a detected value back to the controller 8, whereby the controller 8 determines whether the proximal circulation pump 433 can be operated normally according to the pressure value, and then adjusts the operation state of the proximal circulation pump 433 according to a specific operation condition.

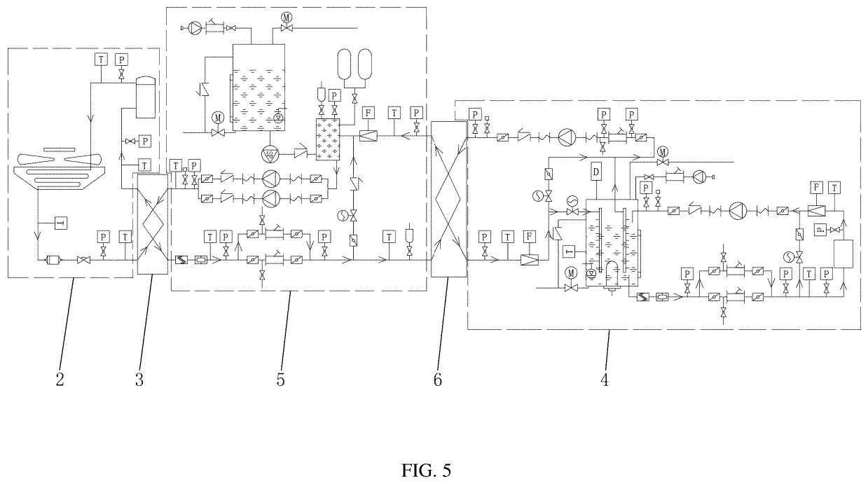

As shown in FIG. 3 and FIG. 5, FIG. 3 is a schematic diagram of a system architecture in a second specific implementation according to the present application, and FIG. 5 is a schematic diagram of specific system modules of the system architecture shown in FIG. 3.

In a second implementation provided by the present application, it is considered that a short distance between the cold source circulation system 2 and the liquid supply circulation system 4 when integrated on the cabinet 1 may cause mutual interference between a cold source and a heat source, leading to adverse consequences. Simultaneously, during server operation, the heat generated by the load 7 may undergo frequent changes within a short period of time, consequently causing the cooling capacity required by the liquid supply circulation system 4 to change frequently accordingly, and ultimately resulting in frequent start and stop of the cold source circulation system 2 (similar to frequent start and stop of an air conditioner), thereby leading to abnormally high energy consumption. In view of this, in the present embodiment, the liquid cooling device with self-configuring cold and heat sources includes a cabinet 1, a cold source circulation system 2, a first heat exchanger 3, a liquid supply circulation system 4, and a controller 8, and further includes an isolated circulation system 5 and a second heat exchanger 6. Similarly, the isolated circulation system 5 and the second heat exchanger 6 are also integrated on the cabinet 1.

A main function of the isolated circulation system 5 is to serve as a heat transfer bridge. The isolated circulation system transfers heat absorbed by cooling liquid to a refrigerant in the cold source circulation system 2 by utilizing an intermediate heat-conducting medium, thereby completing a cooling process of the cooling liquid. Moreover, the cooling liquid at a specified temperature can be provided to the load 7. At the same time, the isolated circulation system 5 can also serve as a buffer component, and physically isolates the cold source circulation system 2 from the liquid supply circulation system 4, thereby avoiding the mutual interference between a cold source and a heat source, and further avoiding the frequent start and stop of the cold source circulation system 2 caused by frequent changes of a cooling capacity required by the liquid supply circulation system 4.

Specifically, the isolated circulation system 5 is disposed between the cold source circulation system 2 and the liquid supply circulation system 4, and configured to drive the intermediate heat-conducting medium to circularly flow along a preset path, and to transfer the heat from the cooling liquid in the liquid supply circulation system 4 to the refrigerant in the cold source circulation system 2 through the first heat exchanger 3.

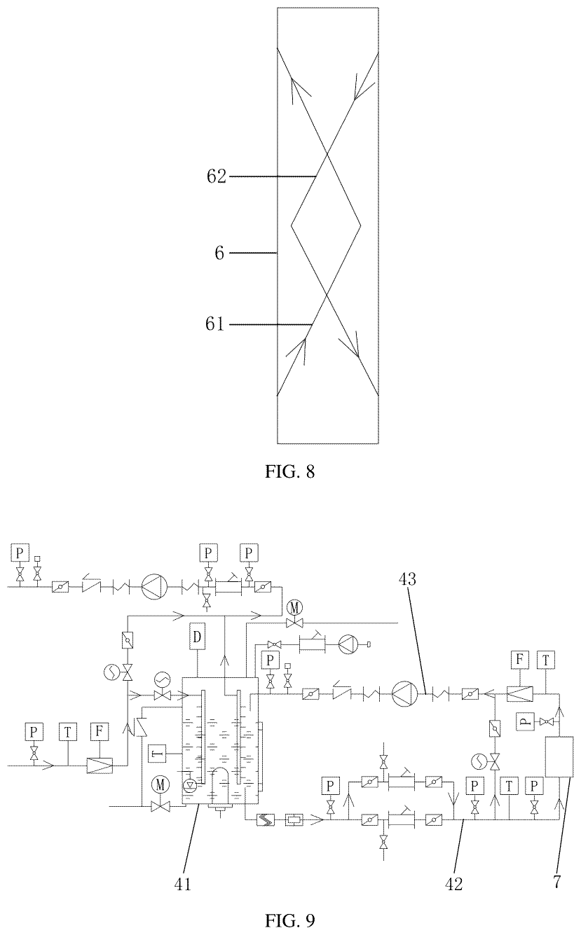

As shown in FIG. 8, FIG. 8 is a schematic structural diagram of a second heat exchanger 6.

The second heat exchanger 6 is connected between the isolated circulation system 5 and the liquid supply circulation system 4, and configured to facilitate heat exchange between the intermediate heat-conducting medium and the cooling liquid after absorbing heat. Specifically, a structure of the second heat exchanger 6 is similar to the first heat exchanger 3, a heat absorbing pipeline 61 and a heat release pipeline 62 are provided inside the second heat exchanger, where the heat absorbing pipeline 61 is configured for the intermediate heat-conducting medium in the isolated circulation system 5 to flow, and the heat release pipeline 62 is configured for the cooling liquid in the liquid supply circulation system 4 to flow, thereby achieving the heat absorption of the intermediate heat-conducting medium and the heat release of the cooling liquid.

With the configuration, after absorbing the heat of the load 7, the cooling liquid may first exchange heat with the low-temperature intermediate heat-conducting medium in the second heat exchanger 6, the heat is transferred to the intermediate heat-conducting medium, and the intermediate heat-conducting medium continues to flow circularly and transfers the heat again to the refrigerant, thereby achieving twice carrying processes of the heat from the load 7. Compared with the foregoing first specific implementation, the heat transfer distance and flow is relatively long; however, the physical isolation between the cold source and the heat source is achieved, and the buffer between the cold source circulation system 2 and the liquid supply circulation system 4 is achieved.

As shown in FIG. 13, FIG. 13 is a schematic structural diagram of an isolated circulation system 5.

In a specific embodiment of the isolated circulation system 5, the isolated circulation system 5 mainly includes an isolated liquid supply module 51 and an isolated liquid return module 52.

The isolated liquid supply module 51 is entirely configured to convey the intermediate heat-conducting medium after releasing the heat in the first heat exchanger 3 to the second heat exchanger 6. Specifically, an inlet of the isolated liquid supply module 51 is in communication with the outlet of the condensation heat exchange pipeline 32 of the first heat exchanger 3, and an outlet of the isolated liquid supply module 51 is in communication with the inlet of the heat absorbing pipeline 61 of the second heat exchanger 6.

The isolated liquid return module 52, as a whole, serves as a power center of the isolated circulation system 5, is mainly configured to provide a driving force for the circulation of the intermediate heat-conducting medium, and has multiple functions such as power output, pressure stabilization, flow stabilization, and system state monitoring. Specifically, an inlet of the isolated liquid return module 52 is in communication with an outlet of the heat absorbing pipeline 61 of the second heat exchanger 6, and an outlet of the isolated liquid return module 52 is in communication with the inlet of the condensation heat exchange pipeline 32 of the first heat exchanger 3.

As shown in FIG. 14, FIG. 14 is a schematic structural diagram of an isolated liquid supply module 51.

In a specific embodiment of the isolated liquid supply module 51, the isolated liquid supply module 51 mainly includes a main liquid supply pipe 511 and a branch liquid supply pipe 512. An inlet of the main liquid supply module 511 is in communication with the outlet of the condensation heat exchange pipeline 32 of the first heat exchanger 3, and an outlet of the main liquid supply module 511 is in communication with the inlet of the heat absorbing pipeline 61 of the second heat exchanger 6. An inlet of the branch liquid supply pipe 512 is in communication with the main liquid supply pipe 511, and an outlet of the branch liquid supply pipe 512 is in communication with the isolated liquid return module 52. Meanwhile, a branch regulation valve 513 is disposed on the branch liquid supply pipe 512. The branch regulation valve 513 is in a closed state under a normal condition. However, when a cooling capacity supplied by the main liquid supply pipe 511 to the heat absorbing pipeline 61 of the second heat exchanger 6 exceeds the heat released by the heat release pipeline 62 of the second heat exchanger 6, the cooling capacity of the intermediate heat-conducting medium is excessive. In this situation, the branch regulation valve 513 is automatically opened under the control of the controller 8, allowing a portion of the intermediate heat-conducting medium to flow directly into the isolated liquid return module 52 via the branch liquid supply pipe 512 without flowing through the second heat exchanger 6, thereby reducing an amount of the intermediate heat-conducting medium entering the heat absorbing pipeline 61 of the second heat exchanger 6, preventing over-cooling of the cooling liquid in the liquid supply circulation system 4, and ensuring that the heat absorbed by the isolated circulation system 5 aligns with the heat generated by the load 7.

Furthermore, to accurately detect an overall operation state of the isolated liquid supply module 51, an eighth temperature sensor 514 and a ninth temperature sensor 515 are additionally provided in the present embodiment.

The eighth temperature sensor 514 is mainly configured to detect the temperature of the intermediate heat-conducting medium after completing heat exchange in the first heat exchanger 3, and feed a detected value back to the controller 8, whereby the controller 8 adjusts the operation state of the isolated circulation system 5 according to a specific application requirement.

The ninth temperature sensor 515 is mainly used to detect the temperature of the intermediate heat-conducting medium entering the second heat exchanger 6, and feed a detected value back to the controller 8, whereby the controller 8 adjusts the operation state of the isolated circulation system 5 according to the detected value and a specific operation condition of the system, thereby ensuring that the intermediate heat-conducting medium entering the second heat exchanger 6 meets the system requirement.

Moreover, an automatic exhaust valve 516 is also additionally provided in the present embodiment. Specifically, the automatic exhaust valve 516 is disposed at the outlet of the main liquid supply pipe 511 and is mainly configured to automatically discharge gas entrapped in the main liquid supply pipe 511, thereby preventing pipeline from being damaged by cavitation caused by the gas in the pipeline.

For other accessory components of the isolated liquid supply module 51, refer to the foregoing cold plate liquid supply module 42. Details are not repeated here.

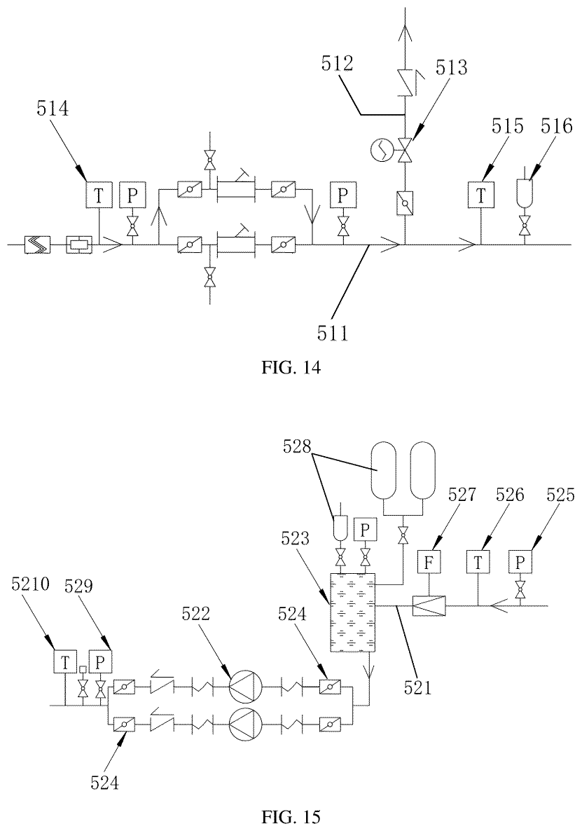

As shown in FIG. 15, FIG. 15 is a schematic structural diagram of an isolated liquid return module 52.

In a specific embodiment of the isolated liquid return module 52, the isolated liquid return module 52 mainly includes a main liquid return pipe 521, an isolated circulation pump 522, and a pressure stabilizing tank 523. An inlet of the main liquid return pipe 521 is in communication with the outlet of the heat absorbing pipeline 61 of the second heat exchanger 6, and an outlet of the main liquid return module 521 is in communication with the inlet of the condensation heat exchange pipeline 32 of the first heat exchanger 3. The isolated circulation pump 522 is disposed on the main liquid return pipe 521, and is mainly configured to drive the intermediate heat-conducting medium to flow circularly in the main liquid supply pipe 511 and the main liquid return pipe 521. The pressure stabilizing tank 523 is serially connected in the main liquid return pipe 521, and is mainly configured to regulate and control pressure and/or a flow rate of the intermediate heat-conducting medium in the isolated circulation system 5 according to a preset target parameter. With the configuration, the intermediate heat-conducting medium is driven by the isolated circulation pump 522 to flow circularly in the main liquid return pipe 521, the pressure stabilizing tank 523, and the main liquid supply pipe 511.

In a specific embodiment of the isolated circulation pump 522, at least two isolated circulation pumps 522 are provided. In the present embodiment, the two isolated circulation pumps 522 are taken as an example for description, and the two isolated circulation pumps 522 are parallel connected onto the main liquid return pipe 521. At the same time, third on-off valves 524 are disposed respectively at both the inlet and outlet ends of the isolated circulation pumps 522, the third on-off valves 524 are mainly configured to control the on-off states of both the inlet and outlet ends of the isolated circulation pumps 522, and when the isolated circulation pumps 522 need to be overhauled, the isolated circulation pumps 522 can be separated from branches in which the isolated circulation pumps are located. With the configuration, the third on-off valves 524 and the isolated circulation pumps 522 collectively form a pump-driving assembly of the isolated circulation system 5. The pump-driving assembly employs a dual-pump (one-on-operation, and one-on-standby) in-turn operation design, whereby it is ensured that the normal operation of the system is not affected when one pump requires shut-down for maintenance, and moreover, issues such as motor over-heating, thermal degradation, efficiency reduction, and shortened service life caused by long-time operation of a single pump can be avoided, thereby effectively enhancing both the service life and operation efficiency of the pump-driving assembly. At the same time, the two third on-off valves 524 are cooperated to control on/off of each branch in which each of the isolated circulation pumps 522 is located, whereby maintenance of related components such as the pump-driving assembly can be implemented without system shutdown, thereby avoiding waste of manpower and resources caused by large-scale liquid discharge, and preventing increases in maintenance difficulty and cost.

Furthermore, to accurately detect an overall operation state of the isolated liquid return module 52, a ninth pressure sensor 525, a tenth temperature sensor 526, a third flow meter 527, a tenth pressure sensor 529, and an eleventh temperature sensor 5210 are additionally provided in the present embodiment.

The ninth pressure sensor 525 is mainly configured to detect the pressure at the outlet end of the heat absorbing pipeline 61 of the second heat exchanger 6, and feed a detected value back to the controller 8, whereby the controller 8 can compare the current pressure value with the inlet pressure of the heat absorbing pipeline 61 of the second heat exchanger 6, to determine whether the current system operation state meets the actual use requirements, and a pressure difference control mode of the system is achieved.

The tenth temperature sensor 526 is mainly configured to detect the temperature of the intermediate heat-conducting medium that absorbs the heat of the cooling liquid, and feed the detected value back to the controller 8, whereby the controller 8 can compare the current temperature value with the detected value of the ninth temperature sensor 515, to determine whether the current operation state of the isolated circulation system 5 can meet the actual operation requirements.

The third flow meter 527 is mainly configured to detect a flow rate of the circulation intermediate heat-conducting medium in the isolated circulation system 5, and feed the detected value back to the controller 8, whereby the controller 8 can monitor the flow rate of the intermediate heat-conducting medium in real time and make relevant adjustments according to the actual requirements.

The tenth pressure sensor 529 is mainly configured to detect the pressure at the outlet of the main liquid return pipe 521, and feed the detected value back to the controller 8, whereby the controller 8 determines whether the pump-driving assembly can be operated normally according to the pressure value, and determines the operation state of the first heat exchanger 3 by comparing the detected pressure value with the outlet pressure of the condensation heat exchange pipeline 32 in the first heat exchanger 3.

The eleventh temperature sensor 5210 is mainly configured to detect the temperature of the intermediate heat-conducting medium before the intermediate heat-conducting medium enters the first heat exchanger 3, and feed the detected value back to the controller 8, whereby the controller 8 determines a heat dissipation and cooling effect of the intermediate heat-conducting medium according to the current detected value together with the detected value of the eighth temperature sensor 514, thereby determining the operation state of the first heat exchanger 3.

To achieve a pressure and flow stabilization effect of the pressure stabilizing tank 523, in the present embodiment, a pressure and flow stabilizing component 528 is additionally provided on the pressure stabilizing tank 523. Specifically, the pressure and flow stabilizing component 528 mainly includes a bag-type expansion tank and an automatic exhaust valve 516, and is mainly configured to adjust parameters such as pressure and/or a flow rate of the intermediate heat-conducting medium in the pressure stabilizing tank 523 by means of the bag-type expansion tank, the automatic exhaust valve 516, and large flow paths for flow reduction when the intermediate heat-conducting medium flows circularly, thereby achieving a constant-pressure and constant-flow operation mode of the intermediate heat-conducting medium.

For other accessory components of the isolated liquid return module 52, refer to the foregoing cold plate liquid return module 43. Details are not repeated here.

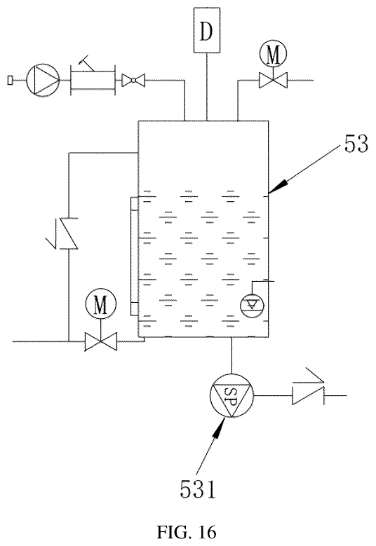

As shown in FIG. 16, FIG. 16 is a schematic structural diagram of a liquid replenishment tank 53.

Furthermore, in consideration of a loss of the intermediate heat-conducting medium, a liquid replenishment tank 53 is also additionally provided in the present embodiment. Specifically, a preset amount of intermediate heat-conducting medium is stored in the liquid replenishment tank 53, an outlet of the liquid replenishment tank 53 is in communication with the pressure stabilizing tank 523, and is mainly configured to replenish the intermediate heat-conducting medium when the amount of the intermediate heat-conducting medium in the pressure stabilizing tank 523 is reduced, thereby ensuring that the flow rate of the intermediate heat-conducting medium is kept within a target range during the circulation. At the same time, to facilitate the automatic replenishment of the intermediate heat-conducting medium, in the pressure stabilizing tank 523, into the pressure stabilizing tank 523, an automatic liquid replenishment pump 531 is also configured at the bottom of the liquid replenishment tank 53 in the present embodiment, the automatic liquid replenishment pump 531 is in signal connection with the controller 8, and when a water level in the pressure stabilizing tank 523 is less than a preset threshold, the controller 8 automatically controls the automatic liquid replenishment pump 531 to operate, thereby implementing automatic liquid replenishment. For other accessory components of the liquid replenishment tank 53, refer to the accessory components on the foregoing temperature regulation water storage tank 411. Details are not repeated here.

The liquid cooling device with self-configuring cold and heat sources provided by the present application mainly includes the cabinet, the cold source circulation system, the first heat exchanger, the liquid supply circulation system, and the controller; and the cabinet is a main component of the device, and is mainly configured to install and contain other components of the device, and the cold source circulation system, the first heat exchanger, the liquid supply circulation system, and the controller are all integrated onto the cabinet to achieve the integrated installation, whereby a simple cold-plate liquid cooling environment is constructed in the cabinet. The cold source circulation system is disposed on the cabinet, and mainly configured to drive the refrigerant to circularly flow along the preset path and perform a refrigeration operation on the refrigerant during the circulation of the refrigerant, to cool the refrigerant and form a low-temperature medium that is mainly configured to provide a cold source for the constructed cold-plate liquid cooling environment. The liquid supply circulation system is disposed on the cabinet, and mainly configured to drive the cooling liquid to circularly flow along the preset path, and drive the cooling liquid to flow through the cold plate during the circulation of the cooling liquid, where the cold plate is kept in tight contact with the load (a heating element such as a server component), whereby the cooling liquid can absorb the heat of the load through the cold plate, to implement heat dissipation for the load. The first heat exchanger is also disposed on the cabinet, specifically connected between the cold source circulation system and the liquid supply circulation system, and mainly configured to facilitate heat exchange between the cold source circulation system and the liquid supply circulation system. To be specific, when the cooled refrigerant (the low-temperature medium) flows through the first heat exchanger during circular flowing, the cooling liquid (a high-temperature medium) absorbing the heat of the load also flows through the first heat exchanger during the circulation, whereby the refrigerant exchanges heat with the cooling liquid in the first heat exchanger, the cooling liquid absorbing the heat of the load transfers the absorbed heat to the refrigerant, the cooled cooling liquid continues to flow circularly and absorb the heat of the load again, and the procedure repeats. The controller is at least kept in signal connection with the cold source circulation system, and is mainly configured to control the operation state of the cold source circulation system according to the actual heat dissipation requirement (i.e., a cooling capacity demand) of the load, whereby the cooling capacity provided by the refrigerant in the cold source circulation system during each heat exchange with the cooling liquid in the liquid supply circulation system is closely equivalent to the heat absorbed by the cooling liquid, thereby ensuring that the cooling capacity provided by the cold source circulation system meets the actual heat dissipation requirement of the load.

The present application has the beneficial effects that the refrigerant is cooled by the cold source circulation system and driven to circularly flow, whereby the supply of the cold source can be implemented; the cooling liquid is driven by the liquid supply circulation system to circularly flow and flow through the cold plate, whereby the cold-plate liquid cooling can be implemented for the load; a heat exchange space is provided by the first heat exchanger, whereby the cooling liquid in the liquid supply circulation system can exchange the heat of the load with the refrigerant in the cold source circulation system, thereby continuously implementing the load-plate liquid cooling and heat dissipation for the load; the cold source circulation system, the first heat exchanger, and the liquid supply circulation system are integrated on the cabinet, collectively forming a simplified cold-plate liquid cooling environment with the cabinet serving as a structural platform, thereby achieving engineering-free design of the cold-plate liquid cooling environment, requiring no additional outdoor chillers, cooling towers, primary/secondary cooling liquid circulation pipelines, or power supplies in scenes such as an air-cooled data center, also avoiding the need of engineered modification for a heat dissipation environment of the server, greatly reducing the configuration cost, configuration difficulty, and configuration period, and facilitating popularization in the air-cooled data centers and similar settings; and at the same time, the controller controls the operation state of the cold source circulation system according to the heat dissipation requirement of the load, whereby the cooling capacity provided by the cold source circulation system is ensured to meet the actual heat dissipation requirement of the load as far as possible, thereby avoiding the problems such as insufficient cooling capacity or excessive cooling capacity.

In conclusion, the liquid cooling device with self-configuring cold and heat sources can achieve an engineer-free design for cold-plate liquid cooling environment construction, and facilitate convenient and low-cost cold-plate liquid cooling for the servers and accurate control of cooling capacity supply.

The above description of the disclosed embodiments enables those skilled in the art to implement or use the present application. Various modifications to these embodiments are apparent to those skilled in the art. The general principles defined herein may be implemented in other embodiments without departing from the spirit or scope of the present application. Therefore, the present application may not be limited to these embodiments described herein, but shall conform to the widest scope consistent with the principles and novel characteristics disclosed herein.

1. A liquid cooling device with self-configuring cold and heat sources, comprising a cabinet, a cold source circulation system, a first heat exchanger, a liquid supply circulation system, and a controller;
wherein the cold source circulation system, the first heat exchanger, the liquid supply circulation system, and the controller are integrated within the cabinet;
the cold source circulation system is configured to drive a refrigerant to circularly flow along a preset path, and cool the refrigerant;
the liquid supply circulation system is configured to drive cooling liquid to circularly flow along a preset path, and drive the cooling liquid to flow through a cold plate to absorb heat from a load;
the first heat exchanger is connected between the cold source circulation system and the liquid supply circulation system, and is configured to facilitate heat exchange between the cooled refrigerant and the cooling liquid after absorbing heat;
the controller is in signal connection with the cold source circulation system, and is configured to control an operation state of the cold source circulation system according to a heat dissipation requirement of the load;
the liquid supply circulation system comprises a temperature regulation module, a cold plate liquid supply module, and a cold plate liquid return module;
an inlet of the temperature regulation module is in communication with an outlet of a condensation heat exchange pipeline of the first heat exchanger, and configured to adjust a temperature of the cooling liquid, and the temperature regulation module is in signal connection with the controller, to control an operation state of the temperature regulation module according to the heat dissipation requirement of the load;
an inlet of the cold plate liquid supply module is in communication with an outlet of the temperature regulation module, and an outlet of the cold plate liquid supply module is in communication with an inlet of the load, and configured to supply liquid to the load;
an inlet of the cold plate liquid return module is in communication with an outlet of the load, and an outlet of the cold plate liquid return module is in communication with an inlet of the condensation heat exchange pipeline of the first heat exchanger, and configured to drive the cooling liquid to circularly flow;
the temperature regulation module comprises a temperature regulation water storage tank for temporary storage of the cooling liquid, a heater disposed in the temperature regulation water storage tank, and a water tank temperature sensor for detecting the temperature of the cooling liquid in the temperature regulation water storage tank; and the water tank temperature sensor and the heater are both in signal connection with the controller, and are configured to control an operation state of the heater according to a detected value of the water tank temperature sensor and the heat dissipation requirement of the load;
the liquid cooling device further comprises an isolated circulation system and a second heat exchanger;
the isolated circulation system and the second heat exchanger are both integrated on the cabinet;
the isolated circulation system is disposed between the cold source circulation system and the liquid supply circulation system, and is configured to drive an intermediate heat-conducting medium to circularly flow along a third preset path, and transfer heat from the cooling liquid in the liquid supply circulation system to the refrigerant in the cold source circulation system through the first heat exchanger; and
the second heat exchanger is connected between the isolated circulation system and the liquid supply circulation system, and is configured to facilitate heat exchange between the intermediate heat-conducting medium and the cooling liquid after absorbing heat.

2. The liquid cooling device with self-configuring cold and heat sources according to claim 1, wherein the cold source circulation system comprises a compressor, a condenser, and an expansion valve; and
wherein an outlet of the compressor is in communication with an inlet of the condenser, an outlet of the condenser is in communication with an inlet of the expansion valve, an outlet of the expansion valve is in communication with an inlet of an evaporation heat exchange pipeline of the first heat exchanger, and an outlet of the evaporation heat exchange pipeline of the first heat exchanger is in communication with an inlet of the compressor.

3. The liquid cooling device with self-configuring cold and heat sources according to claim 2, further comprising a first temperature sensor for detecting an inlet temperature of the evaporation heat exchange pipeline, a second temperature sensor for detecting an outlet temperature of the evaporation heat exchange pipeline, a first pressure sensor for detecting inlet pressure of the evaporation heat exchange pipeline, and a second pressure sensor for detecting outlet pressure of the evaporation heat exchange pipeline; and
wherein the controller is in signal connection with the first temperature sensor, the second temperature sensor, the first pressure sensor, and the second pressure sensor, and is configured to determine a current heat dissipation requirement of the load according to detected values of the first temperature sensor, the second temperature sensor, the first pressure sensor and the second pressure sensor, and control an operation state of the compressor according to the current heat dissipation requirement.

4. The liquid cooling device with self-configuring cold and heat sources according to claim 2, further comprising a filter dehumidifier connected between the outlet of the condenser and the inlet of the expansion valve, wherein the filter dehumidifier is configured to filter water and impurities in the refrigerant.

5.-6. (canceled)

7. The liquid cooling device with self-configuring cold and heat sources according to claim 1, wherein the temperature regulation module further comprises a liquid level meter for detecting a liquid level of the cooling liquid that is temporarily stored in the temperature regulation water storage tank, and a liquid replenishment mechanism and a liquid discharge mechanism that are in communication with the temperature regulation water storage tank, the liquid level meter is in signal connection with the controller, and is configured to control operation states of the liquid replenishment mechanism and the liquid discharge mechanism according to a difference between a detected value of the liquid level meter and a preset threshold.

8. The liquid cooling device with self-configuring cold and heat sources according to claim 1, wherein the cold plate liquid supply module comprises a distal liquid inlet pipe and a proximal liquid inlet pipe;
an inlet of the distal liquid inlet pipe is in communication with the outlet of the condensation heat exchange pipeline of the first heat exchanger, and an outlet of the distal liquid inlet pipe is in communication with the temperature regulation water storage tank; and an inlet of the proximal liquid inlet pipe is in communication with the temperature regulation water storage tank, and an outlet of the proximal liquid inlet pipe is in communication with the inlet of the load.

9. The liquid cooling device with self-configuring cold and heat sources according to claim 8, wherein the cold plate liquid supply module further comprises a distal bypass liquid inlet pipe and a distal bypass regulation valve;
an inlet of the distal bypass liquid inlet pipe is in communication with the distal liquid inlet pipe, and an outlet of the distal bypass liquid inlet pipe is in communication with the cold plate liquid return module; and
the distal bypass regulation valve is disposed on the distal bypass liquid inlet pipe, and configured to enable a portion of the cooling liquid to enter the cold plate liquid return module through the distal bypass liquid inlet pipe when the detected value of the water tank temperature sensor is less than a preset threshold.

10. The liquid cooling device with self-configuring cold and heat sources according to claim 8, wherein the cold plate liquid supply module further comprises a water distributor; and
the water distributor is disposed in the temperature regulation water storage tank, an inlet of the water distributor is in communication with the outlet of the distal liquid inlet pipe, the water distributor is provided with a plurality of outlets distributed along a height direction of the temperature regulation water storage tank, and configured to equally allocate the cooling liquid to each layer in the temperature regulation water storage tank.

11. The liquid cooling device with self-configuring cold and heat sources according to claim 8, wherein the cold plate liquid supply module further comprises a proximal bypass liquid inlet pipe and a proximal bypass regulation valve;
an inlet of the proximal bypass liquid inlet pipe is in communication with the proximal liquid inlet pipe, and an outlet of the proximal bypass liquid inlet pipe is in communication with the cold plate liquid return module; and
the proximal bypass regulation valve is disposed on the proximal bypass liquid inlet pipe, and configured to enable a portion of the cooling liquid to enter the cold plate liquid return module through the proximal bypass liquid inlet pipe when a cooling liquid demand of the load is less than a minimum flow rate of returned liquid of the cold plate liquid return module.

14. The liquid cooling device with self-configuring cold and heat sources according to claim 8, wherein the cold plate liquid supply module further comprises at least two filters that are parallel connected on the proximal liquid inlet pipe, first on-off valves that are separately configured at inlet and outlet ends of the at least two filters, and water quality sampling valves in communication with inlets of the at least two filters respectively; and
the first on-off valves are is configured to close a branch in which a corresponding one of the at least two filters is located when a filter element of the corresponding one of the at least two filters is maintained.

15. The liquid cooling device with self-configuring cold and heat sources according to claim 14, wherein the cold plate liquid supply module further comprises monitoring pressure sensors that are disposed at the inlet and outlet ends of each of the at least two filters and each of the monitoring pressure sensors is in signal connection with the controller, and is configured to enable the controller to issue a filter element maintenance alarm when a difference between detected values of the monitoring pressure sensors at both ends is greater than a preset threshold.

16. The liquid cooling device with self-configuring cold and heat sources according to claim 1, wherein the cold plate liquid return module comprises a proximal liquid return pipe, a distal liquid return pipe, a proximal circulation pump, and a distal circulation pump;
an inlet of the proximal liquid return pipe is in communication with the outlet of the load, and an outlet of the proximal liquid return pipe is in communication with the temperature regulation water storage tank;
an inlet of the distal liquid return pipe is in communication with the temperature regulation water storage tank, and an outlet of the distal liquid return pipe is in communication with the inlet of the condensation heat exchange pipeline of the first heater exchanger;
the proximal circulation pump is disposed on the proximal liquid return pipe, and configured to drive the cooling liquid to flow into the temperature regulation water storage tank from the outlet of the load; and
the distal circulation pump is disposed on the distal liquid return pipe, and configured to drive the cooling liquid to flow into the inlet of the condensation heat exchange pipeline of the first heat exchanger from the temperature regulation water storage tank.

17. The liquid cooling device with self-configuring cold and heat sources according to claim 16, wherein inlet and outlet ends of both the proximal circulation pump and the distal circulation pump are in communication with vibration damping pipes, and the vibration damping pipes are configured to eliminate an installation error generated when the proximal circulation pump or the distal circulation pump is connected with a pipeline and reduce vibration generated when the proximal circulation pump or the distal circulation pump is operated through elastic deformation.

18. The liquid cooling device with self-configuring cold and heat sources according to claim 16, wherein inlet and outlet ends of both the proximal circulation pump and the distal circulation pump are in communication with second on-off valves, and the second on-off valves are configured to close a corresponding one of the proximal liquid return pipe or the distal liquid return pipe when the proximal circulation pump or the distal circulation pump is overhauled.

19. The liquid cooling device with self-configuring cold and heat sources according to claim 16, wherein the cold plate liquid return module further comprises a water collector; and
the water collector is disposed in the temperature regulation water storage tank, an outlet of the water collector is in communication with the inlet of the distal liquid return pipe, and the water collector is provided with a plurality of inlets that are distributed along a height direction of the temperature regulation water storage tank, and configured to enable the cooling liquid at each layer in the temperature regulation water storage tank to be pumped out by the distal circulation pump.

20. (canceled)

21. The liquid cooling device with self-configuring cold and heat sources according to claim 1, wherein the isolated circulation system comprises an isolated liquid supply module and an isolated liquid return module;
an inlet of the isolated liquid supply module is in communication with the outlet of the condensation heat exchange pipeline of the first heat exchanger, and an outlet of the isolated liquid supply module is in communication with an inlet of a heat absorbing pipeline of the second heat exchanger; and
an inlet of the isolated liquid return module is in communication with an outlet of the heat absorbing pipeline of the second heat exchanger, and an outlet of the isolated liquid return module is in communication with the inlet of the condensation heat exchange pipeline of the first heat exchanger.

22. The liquid cooling device with self-configuring cold and heat sources according to claim 21, wherein the isolated liquid supply module comprises a main liquid supply pipe and a branch liquid supply pipe;
an inlet of the main liquid supply pipe is in communication with the outlet of the condensation heat exchange pipeline of the first heat exchanger, and an outlet of the main liquid supply pipe is in communication with the inlet of the heat absorbing pipeline of the second heat exchanger;
an inlet of the branch liquid supply pipe is in communication with the main liquid supply pipe, and an outlet of the branch liquid supply pipe is in communication with the isolated liquid return module; and
the branch liquid supply pipe is provided with a branch regulation valve, the branch regulation valve is configured to enable a portion of the intermediate heat-conducting medium to enter the isolated liquid return module through the branch liquid supply pipe when a cooling capacity supplied by the main liquid supply pipe to the heat absorbing pipeline of the second heat exchanger is greater than the heat released by a heat release pipeline of the second heat exchanger.

23. The liquid cooling device with self-configuring cold and heat sources according to claim 22, wherein the isolated liquid return module comprises a main liquid return pipe, an isolated circulation pump, and a pressure stabilizing tank;
an inlet of the main liquid return pipe is in communication with the outlet of the heat absorbing pipeline of the second heat exchanger, and an outlet of the main liquid return pipe is in communication with the inlet of the condensation heat exchange pipeline of the first heat exchanger;
the isolated circulation pump is disposed on the main liquid return pipe, and configured to drive the intermediate heat-conducting medium to circularly flow in the main liquid supply pipe and the main liquid return pipe; and
the pressure stabilizing tank is serially connected in the main liquid return pipe, and configured to regulate and control at least one of pressure or a flow rate of the intermediate heat-conducting medium in the isolated circulation system according to a preset target parameter.

24. The liquid cooling device with self-configuring cold and heat sources according to claim 23, wherein at least two isolated circulation pumps are provided, and all of the at least two isolated circulation pumps are parallel connected on the main liquid return pipe; and outlet and inlet ends of each of the at least two isolated circulation pumps are provided with third on-off valves, and the third on-off valves are configured to close a branch in which a corresponding one of the at least two isolated circulation pumps is located when the corresponding one of the at least two isolated circulation pumps is maintained.

25. The liquid cooling device with self-configuring cold and heat sources according to claim 23, wherein the isolated circulation system further comprises a liquid replenishment tank, a preset amount of the intermediate heat-conducting medium is stored in the liquid replenishment tank, and an outlet of the liquid replenishment tank is in communication with the pressure stabilizing tank, and configured to replenish the intermediate heat-conducting medium when an amount of the intermediate heat-conducting medium in the pressure stabilizing tank is reduced.
